(19) United States
(12) Patent Application Publication
(10) Pub. No.: US 2023/0170426 A1
(43) Pub. Date: Jun. 1, 2023

(54) UV-TRANSPARENT CONDUCTING FILMS, OPTICAL STACK, AND METHODS OF MAKING THE SAME

(71) Applicant: The Penn State Research Foundation, University Park, PA (US)

(72) Inventors: Joseph Roth, Elgin, ND (US); Roman Engel-Herbert, Port Matilda, PA (US)

(73) Assignee: The Penn State Research Foundation, University Park, PA (US)

(21) Appl. No.: 17/920,605

(22) PCT Filed: Apr. 22, 2021
(86) PCT No.: PCT/US2021/028639

§ 371 Date: Oct. 21, 2022

Related U.S. Application Data
(60) Provisional application No. 63/013,854, filed on Apr. 22, 2020.

(51) Int. Cl. H01L 31/0224; H01L 33/42

(52) U.S. Cl. CPC H01L 31/022466; H01L 33/42

(57) ABSTRACT

The present disclosure relates to transparent conducting films (TCF). In particular, the disclosed TCF are transparent to ultraviolet (UV) light. The TCF can be grown by radio frequency (RF) sputtering and remain in the advantageous perovskite phase. Optical stacks made of substrates with deposited TCF are also disclosed.

### CROSS-REFERENCE TO RELATED APPLICATIONS

This application claims priority to U.S. Provisional Application Serial No. 63/013,854 filed on Apr. 22, 2020, the content of which is hereby incorporated by reference in its entirety.

### STATEMENT REGARDING FEDERALLY SPONSORED RESEARCH OR DEVELOPMENT

This invention was made with government support under Grant Nos. DGE1255832 and DMR1629477 awarded by the National Science Foundation. The Government has certain rights in the invention.

### FIELD

The present disclosure relates to transparent conducting films (TCF). In particular, the disclosed TCF are transparent to ultraviolet (UV) light. The TCF can be grown by sputtering and remain in the advantageous perovskite phase.

### BACKGROUND

Transparent conducting films (TCF) are critical to many modern electronic devices where a combination of electrical conductivity and optical transparency are required. Examples include liquid crystal displays (LCD), plasma display panels (PDP), touch screens, touch panels, photovoltaic devices, light emitting diodes (LED), photodetectors, and other optoelectronic devices.

At the same time, AlGaN based LED are emerging as replacement candidates for mercury vapor lamps as the most widely employed UV light source. In addition to the enormous advantages LED technology has in efficiency and lamp life over gas discharge lamps, the LED eliminates mercury that is a required material for gas discharge lamps. However, the total output performance of UV LED are presently limited by low light extraction efficiency (LEE) because of significant UV light absorption in conventional TCF that are required in LED.

The low LEE values are a result of the band gap of conventional TCF. For example, the band gaps of Al doped ZnO (AZO) (E_{g} = 3.3 - 3.7 eV) and tin-doped indium oxide (ITO) (E_{g} = 3.8 - 4.0 eV) are too small, leading to large absorption coefficients exceeding 1.0 × 10⁵ cm⁻¹ in the UV range of interest. Thus, ITO and AZO are unsuitable for UV-B (about 290 - 320 nm) and UV-C (about 100 - 290 nm) LEDs.

Following the same conventional approach for designing visible light TCF, skilled persons have also attempted to fabricate TCF for UV light. Under the conventional approach ultra wide band gaps of about 5 eV or more are required for UV transparency. Ultra-wide band gap semiconductors such as α—Ga₂O₃ (E_{g} = 5.3 eV), β—Ga₂O₃ (E_{g} = 4.9 eV), and ZnGa₂O₄ (E_{g} = 5.0 eV) avoid the problem of low optical transparency but have high electrical resistivity. High electrical resistivity generates unwanted voltage drops across electrodes, high dissipative losses in high frequency applications, and high energy loss through joule heating in high current applications. Mitigation of these problems often requires thick films which are time consuming to deposit and severely limit the optical transparency of the film. Attempts to lower electrical resistivity by increasing the dopant concentration have been unsuccessful because the large doping concentrations required often result in crystal lattice expansion which lowers the band gap, thereby increasing absorption of UV light.

There is a need for a TCF that has both high transmissivity to UV spectra and high electrical conductivity. Such a TCF should also be affordable to deploy by way of existing production processes for ITO and AZO, such as sputtering. Finally, the TCF should be capable of being deposited on a diverse range of substrate materials.

### SUMMARY

The present disclosure describes transparent conducting films (TCF). In particular, the disclosed TCF are transparent to ultraviolet (UV) light. The TCF can be grown by sputtering and remain in the advantageous perovskite phase. Optical stacks made of substrates with deposited TCF are also disclosed.

In one embodiment, there is a transparent conductive film (TCF) comprising AₓBO_{3-d} having a transmittance of about 50% to about 95% for light having a wavelength from about 240 nm to about 320 nm when measured for a TCF having a thickness of about 10 nm.

In another embodiment, the transmittance of the TCF is about 80% or more at a wavelength of 550 nm when measured for a TCF having a thickness of 10 nm.

In another embodiment, the TCF comprises AₓBO_{3-d} having a transmittance of about 50% to about 95% for light having a wavelength from about 240 nm to about 320 nm, where A is one or more of a monovalent, divalent, or trivalent cation including Li, Na, K, Rb, Be, Mg, Ca, Sr, Ba, Sc, Y, La, Pr, Nd, Sm, Eu, Gd, Tb, Dy, Ho, Er, Tm, Yb, Lu, B is one or more of Ti, Zr, Hf, Nb, Ta, Cr, Mo, V, or W, x is about 0.30 to about 0.95 and the TCF has a perovskite crystal structure, a perovskite-like crystal structure that approximates a perovskite crystal structure, or some combination of the preceding crystal structures.

In another embodiment, A is four or more of a monovalent, divalent, or trivalent cation including Li, Na, K, Rb, Be, Mg, Ca, Sr, Ba, Sc, Y, La, Pr, Nd, Sm, Eu, Gd, Tb, Dy, Ho, Er, Tm, Yb, or Lu.

In another embodiment, B is four or more of Ti, Zr, Hf, Nb, Ta, Cr, Mo, V, or W.

In another embodiment, the perovskite crystal structure, perovskite-like crystal structure, or combination of the perovskite and perovskite-like crystal structures has an amount of A vacancy of greater than about 15%.

In another embodiment, the ratio of A and O is about 3.

In another embodiment, A is Sr and B is Nb.

In another embodiment, A is Sr and B is Mo.

In another embodiment, the TCF is formed by radio frequency (RF) sputtering.

In one embodiment, there is an optical stack comprising a substrate and a transparent conductive film (TCF) comprising AₓBO_{3-d} having a transmittance of about 50% to about 95% for light having a wavelength from about 240 nm to about 320 nm, wherein A is one or more of a monovalent, divalent, or trivalent cation including Li, Na, K, Rb, Be, Mg, Ca, Sr, Ba, Sc, Y, La, Pr, Nd, Sm, Eu, Gd, Tb, Dy, Ho, Er, Tm, Yb, Lu, B is one or more of Ti, Zr, Hf, Nb, Ta, Cr, Mo, V, or W, x is about 0.30 to about 0.95 and the TCF has a perovskite crystal structure, a perovskite-like crystal structure that approximates a perovskite crystal structure, or some combination of the preceding crystal structures.

In another embodiment, A is four or more of a monovalent, divalent, or trivalent cation including Li, Na, K, Rb, Be, Mg, Ca, Sr, Ba, Sc, Y, La, Pr, Nd, Sm, Eu, Gd, Tb, Dy, Ho, Er, Tm, Yb, or Lu.

In another embodiment, B is four or more of Ti, Zr, Hf, Nb, Ta, Cr, Mo, V, or W.

In another embodiment, the substrate is one or more of SrTiO₃ BaTiO₃, PZT, PMN-PT, BiFeO₃, CaTiO₃, LiNbO₃, ferroelectric compounds, monocrystalline silicon, polycrystalline silicon, amorphous silicon, monocrystalline germanium, polycrystalline germanium, amorphous germanium, quartz, glass, metal, plastic, an oxide coated surface, crystalline sapphire (Al₂O₃), crystalline SiC, crystalline GaN, or monocrystalline (La_{0.3}Sr_{0.7})(Al_{0.65}Ta_{0.35})O₃ (LSAT).

In another embodiment, there is a lattice mismatch between the substrate and the TCF that is greater than about 1%.

In another embodiment, A is Sr and B is Nb.

In another embodiment, A is Sr and B is Mo.

In one embodiment, there is a method of manufacturing an optical stack comprising: providing a substrate, and radio frequency (RF) sputtering a TCF on the substrate, wherein the TCF includes AₓBO_{3-d} having a transmittance of about 50% to about 95% for light having a wavelength from about 240 nm to about 320 nm, where x is about 0.30 to about 0.95 and the resultant TCF has a perovskite crystal structure.

In another embodiment, the RF sputtering is performed in a reducing atmosphere.

### DRAWINGS

Aspects, features, benefits and advantages of the embodiments described herein will be apparent with regard to the following description, appended claims, and accompanying drawings where:

FIG. 1A is a plot of the resistivity p as a function of the thickness of a sputtered TCF formed of SrₓNbO₃.

FIG. 1B is a plot of the carrier concentration n as a function of the thickness of a sputtered TCF formed of SrₓNbO₃.

FIG. 1C is a plot of the electron mobility µ as a function of the thickness of a sputtered TCF formed of SrₓNbO₃.

FIG. 1D is a plot of the sheet resistance Rₛ as a function of the thickness of a sputtered TCF formed of SrₓNbO₃.

FIG. 2A is a plot of the transmission of light through the TCF versus the wavelength of the light for three tested SrₓNbO_{3-d} films of thicknesses of 10.8 nm, 30.2 nm, and 54.5 nm, with markings to show the location of the visible spectrum and a wavelength of 255 nm which is within the UV-C band.

FIG. 2B is a plot of the absorption coefficient of the TCF formed of SrₓNbO_{3-d} for three tested films of thicknesses of 10.8 nm, 30.2 nm, and 54.5 nm, with markings to show the location of the visible spectrum and a wavelength of 255 nm which is within the UV-C band.

FIG. 2C is a plot of the extinction coefficient of the TCF formed of SrₓNbO_{3-d} for three tested films of thicknesses of 10.8 nm, 30.2 nm, and 54.5 nm, with markings to show the location of the visible spectrum and of 255 nm which is within the UV-C band.

FIG. 2D is a plot of the refractive index of the TCF formed of SrₓNbO_{3-d} for three tested films of thicknesses of 10.8 nm, 30.2 nm, and 54.5 nm, with markings to show the location of the visible spectrum and of 255 nm which is within the UV-C band.

FIG. 3 is a plot of the light transmission for a 10 nm thick TCF of SrₓNbO₃ and a 90 nm thick TCF of ITO measured in the visible and UV ranges.

FIG. 4 is plot of the transmission of light through a TCF formed of SrₓMoO_{3-d} for two tested films of thicknesses of 18 nm and 28.7 nm, with markings to show the location of the visible spectrum and of 255 nm which is within the UV-C band.

FIG. 5 is a plot comparing the transmission of light through three TCF formed of SrₓNbO₃, ITO, and SrₓMoO₃, with markings to show the location of the visible spectrum and of 255 nm which is within the UV-C band.

### DETAILED DESCRIPTION

This disclosure is not limited to the particular systems, devices and methods described, as these may vary. The terminology used in the description is for the purpose of describing the particular versions or embodiments only, and is not intended to limit the scope.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

As described herein, a zero subscript used in stoichiometric or non-stoichiometric compounds encompasses both embodiments where the corresponding element is absent and embodiments where the corresponding element is present in trace amounts.

The disclosure describes TCF that are formed of AₓB_{y}O_{3-d} that are described by the composition of the films, the microstructural characteristics, the deposition techniques, the measured optical performance, and the measured electrical performance. In AₓBO_{3-d}, A is a monovalent, divalent, or trivalent cation including one or more of Li, Na, K, Rb, Be, Mg, Ca, Sr, Ba, Sc, Y, La, Pr, Nd, Sm, Eu, Gd, Tb, Yb, or Lu; B is a transition metal including one or more of Ti, Zr, Hf, Nb, Ta, Cr, Mo, V, or W. In some embodiments, four or more cations from the above list for A are employed. In still other embodiments, four or more cations from the above list for B are employed. In the formula AₓB_{y}O_{3-d}, x is about 0.5 to about 1 for y about 1, y is about 0.5 to about 1 for x about 1, and d is about -0.5 to about 0.5. In one embodiment, when A is Sr, Ca, or Ba and B is Nb, x is about 0.2 to about 1. In another embodiment, when A is Sr, Ca, or Ba and B is Mo, x is about 0.2 to about 1. In still another embodiment, when A is Sr, Ca, or Ba and B is W, x is about 0.0 to 1.

The disclosure also describes TCF that are formed of AₓB_{y}O_{3-d} where A is Sr, B is Nb or Mo, and d = 0. Such SrₓNbO_{3-d} or SrₓMoO_{3-d} are described by the composition of the films, the microstructural characteristics, the deposition techniques, the measured optical performance, and the measured electrical performance. The disclosure also describes novel structures and uses of the TCF.

### Composition and Microstructure

According to an embodiment of the disclosure, the TCF are formed of AₓBO_{3-d} that are substantially non-stoichiometric. In particular, AₓBO_{3-d} have substantial cation non-stoichiometry. In some embodiments, the value of x in AₓBO_{3-d} is about 0, about 0.10, about 0.20, about 0.25, about 0.30, about 0.35, about 0.40, about 0.45, about 0.50, about 0.55, about 0.60, about 0.65, about 0.70, about 0.75, about 0.80, about 0.85, about 0.90, about 0.95, about 1.00, or any range that includes one or more of the above amounts as endpoints. In one embodiment, x is about 0.60 to about 0.95. In another embodiment, x is about 0.50 to about 0.95. In another embodiment, x is about 0.30 to about 0.95. In another embodiment, d is about -0.5, about -0.4, about -0.3, about -0.2, about -0.1, about 0, about 0.1, about 0.2, about 0.3, about 0.4, about 0.5, or any range that includes one or more of the above amounts as endpoints.

According to another embodiment of the disclosure, the TCF are formed of SrₓNbO_{3-d} that are substantially non-stoichiometric. In particular, SrₓNbO_{3-d} have substantial cation non-stoichiometry. In some embodiments, the value of x in SrₓNbO_{3-d} is about 0.20, about 0.25, about 0.30, about 0.35, about 0.40, about 0.45, about 0.50, about 0.55, about 0.60, about 0.65, about 0.70, about 0.75, about 0.80, about 0.85, about 0.90, about 0.95, about 1.00, or any range that includes one or more of the above amounts as endpoints. In one embodiment, x is about 0.60 to about 0.95. In another embodiment, x is about 0.50 to about 0.95. In another embodiment, x is about 0.30 to about 0.95.

In some embodiments, the amount of the A is expressed as level of A vacancy in the lattice of the TCF. According to conventional theory, high levels of A vacancy in the lattice of the TCF would be expected to form secondary phases or even amorphous films. Such microstructures would be expected to retain optical transparency but with severely degraded electrical properties. Instead, the inventors surprisingly and unexpectedly found that even high levels of A vacancy actually results in crystalline perovskite TCR having excellent optical and electrical performance. In some embodiments, the amount of A vacancy is about 5%, about 10%, about 15%, about 20%, about 25%, about 30%, about 35%, about 40%, about 45%, about 50%, about 55%, about 60%, about 65%, about 70%, about 75%, or any range that includes one or the above amounts as endpoints. In one embodiment, the A vacancy is about 5% to about 75%, about 5% to about 60%, about 5% to about 50%, about 5% to about 40%, about 5% to about 30%, or any combination of the preceding ranges.

According to another embodiment of the disclosure, the TCF are formed of SrₓMoO_{3-d} that are substantially non-stoichiometric. In particular, SrₓMoO_{3-d} have substantial cation non-stoichiometry. In some embodiments, the value of x in SrₓMoO_{3-d} is about 0.20, about 0.25, about 0.30, about 0.35, about 0.40, about 0.45, about 0.50, about 0.55, about 0.60, about 0.65, about 0.70, about 0.75, about 0.80, about 0.85, about 0.90, about 0.95, about 1.00, or any range that includes one or more of the above amounts as endpoints. In one embodiment, x is about 0.60 to about 0.95. In another embodiment, x is about 0.50 to about 0.95. In another embodiment, x is about 0.30 to about 0.95.

In other embodiments, the amount of the Sr is expressed as level of Sr vacancy in the lattice of the TCF. According to conventional theory, high levels of Sr vacancy in the lattice of the TCF would be expected to form secondary phases or even amorphous films. Such microstructures would be expected to retain optical transparency but with severely degraded electrical properties. Instead, the inventors surprisingly and unexpectedly found that even high levels of Sr vacancy actually results in crystalline perovskite TCR having excellent optical and electrical performance. In some embodiments, the amount of Sr vacancy is about 5%, about 10%, about 15%, about 20%, about 25%, about 30%, about 35%, about 40%, about 45%, about 50%, about 55%, about 60%, about 65%, about 70%, about 75%, or any range that includes one or the above amounts as endpoints. In one embodiment, the Sr vacancy is about 5% to about 75%, about 5% to about 60%, about 5% to about 50%, about 5% to about 40%, about 5% to about 30%, or any combination of the preceding ranges.

The overall crystalline structure of SrₓNbO_{3-d} or SrₓMoO_{3-d} is only weakly dependent on the ratio of Sr and Nb or Mo, if at all. In some embodiments, the crystalline structure is a perovskite crystal structure, a perovskite-like crystal structure that approximates a perovskite crystal structure, or some combination of the preceding crystal structures. In other embodiments, the crystalline structure is a pseudo-cubic perovskite crystal structure that includes minute structural distortion to orthorhombic or tetragonal crystal structures. Despite the high levels of vacancy in comparison to conventional TCF, the TCF of the disclosure remains a perovskite crystal structure. In still further embodiments, the perovskite crystal structure is a cubic perovskite crystal structure. In some embodiments, the cubic perovskite structure has a lattice parameter of about 4.024 Å. The lattice parameter of SrₓNbO₃ or SrₓMoO₃ decreases as x in Srₓ decreases. In some embodiments, x is about 0.5 to about 1. In other embodiments, x is about 0.5, 0.6, 0.7, 0.8, 0.9, or 1.0, or any range formed by one or more of the preceding values. The cubic perovskite crystal structure is nearly maintained even when there is substantial Sr vacancy, such as greater than about 20%, greater than about 40%, or greater than about 60%.

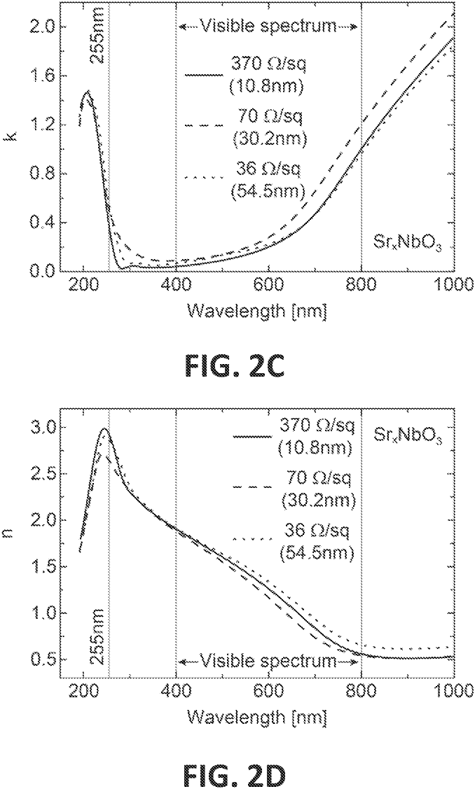

In some embodiments, the formula of the TCF is SrₓNbO_{3-d}, the performance of which is shown in FIG. 3 in comparison to other TCF that contain conventional ITO. In these embodiments, the ratio between Sr and O is about 1:3, and the resultant film has Sr vacancies that are less than 5%. Furthermore, this corresponds to a value of x in the above formulas of about 1.

### Deposition Methods

The methods of depositing the TCF on substrates is not limited so long as the desired perovskite crystal structure, amounts of A, Sr amounts, vacancy levels of A, or Sr vacancies of SrₓNbO_{3-d} or SrₓMoO_{3-d} or AₓBO_{3-d} are achieved. In some embodiments, the methods include epitaxial techniques including hybrid molecular beam epitaxy (hMBE) and molecular beam epitaxy (MBE). In other embodiments, the methods include physical vapor deposition (PVD). Examples of PVD include pulsed laser deposition (PLD), radio frequency (RF) sputtering, direct current (DC) sputtering, high-power impulse magnetron sputtering (HiPIMS), or ion beam deposition. In one embodiment, electron beam evaporation of Nb is employed in conjunction with thermal evaporation of Sr. In still further embodiments, the TCF is deposited by way of a sol-gel process.

In some embodiments, the TCF is deposited on a substrate by RF sputtering. RF sputtering has many advantages over similar PVD techniques as well as over MBE. RF sputtering can be achieved with a magnetron or diode driving the sputtering operation, and can be used whether the sputter target or substrate is conductive or non-conductive. RF sputtering also has the advantage that it is much faster than epitaxial techniques such as MBE or hMBE. Furthermore, sputtering techniques generally are scalable and are also compatible with rapid production techniques such as roll-to-roll (R2R) processing.

In all embodiments, including those where the TCF was deposited by PVD including RF sputtering or DC sputtering, the perovskite crystal structure is achieved. In some embodiments, the perovskite crystal structure is a cubic perovskite crystal structure.

While not wishing to be bound by theory, it is believed that the growth of SrₓNbO_{3-d} is challenging because in the SrO—Nb₂O₅ system, the Sr2Nb₂O₇ phase is energetically most favorable due to Nb preferring the 5+ oxidation state. Therefore, in some embodiments, the deposition technique is performed with a reducing atmosphere in order to stabilize the perovskite phase and the Nb +4 oxidation state. The reducing atmosphere is not limited, and includes an excess of inert process gas such as N₂ or Ar, low O₂ partial pressure, CO, H₂, CH₄, and combinations of the above.

In still further embodiments, the perovskite phase is stabilized by introducing Sr vacancies into the film that leave behind two holes that are electrically compensated by the formation of an oxygen vacancy or by allowing two occupied Nb sites to assume the energetically preferred 5+ oxidation state.

The deposition techniques of the disclosure permit the TCF to be deposited on a variety of substrates. The substrates are not limited and include one or more of SrTiO₃ BaTiO₃, PZT, PMN-PT, BiFeO₃, CaTiO₃, LiNbO₃, ferroelectric compounds, monocrystalline silicon, polycrystalline silicon, amorphous silicon, monocrystalline germanium, polycrystalline germanium, amorphous germanium, quartz, glass, metal, plastic, an oxide coated surface, crystalline sapphire (Al₂O₃), crystalline SiC, crystalline GaN, or monocrystalline or polycrystalline (La_{0.3}Sr_{0.7})(Al_{0.65}Ta_{0.35})O₃ (LSAT).

In some embodiments, the different materials of the disclosure results in lattice mismatch between the substrate and the TCF. The lattice mismatch does not substantially impede the or electrical properties of the TCF. In some embodiments, the substrate is monocrystalline or polycrystalline and there is a lattice mismatch between the substrate and the TCF of about 0.5%, about 1.0%, about 1.5%, about 2.0%, about 2.5%, about 3.0%, about 3.5%, about 4.0%, about 4.5%, about 5.0%, about 5.5%, about 6%, about 10%, about 15%, about 16%, about 20%, about 25%, about 30%, or any range of one or more of the preceding values. In one embodiment, the TCF is deposited by RF sputtering on a (001) monocrystalline LSAT substrate and the resulting lattice mismatch between the substrate and the TCF is about 4.0%.

In other embodiments, the substrate is amorphous. When the substrate is amorphous, there is no lattice mismatch because the substrate does not have any long range order.

In some embodiments, the TCF is deposited on a substrate by a sol-gel process. During a sol-gel process, a colloidal suspension is formed and that colloidal suspension is coated on a substrate. After the colloidal suspension is coated onto the substrate, water or other solvent materials that are contained with the coated colloidal suspension are removed by drying. Finally, after drying, the substrate and the dried colloidal suspension are heated to temperatures of about 650° C. to about 1000° C. in order to sinter the dried colloidal suspension and thereby form the TCF.

### Optical and Electrical Performance

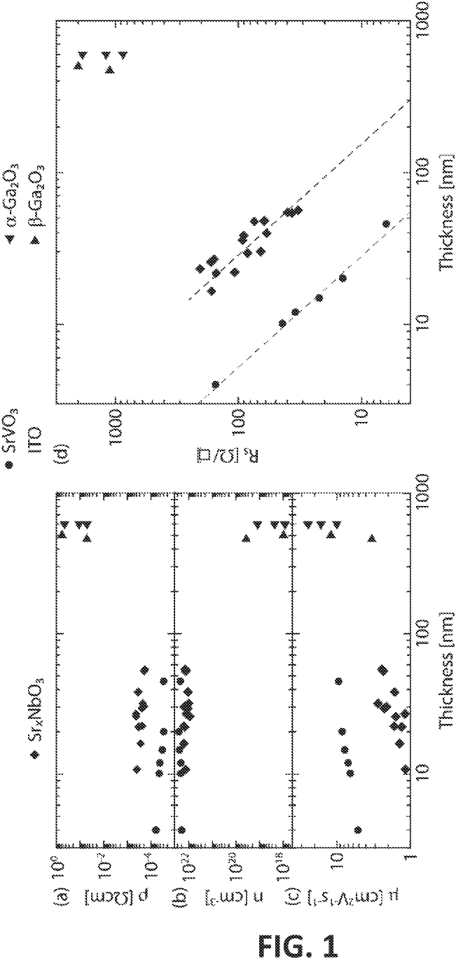

The TCF of the disclosure have excellent electrical properties when compared to other TCF such as ITO, SrVO₃, and Sn-doped Ga₂O₃. Electrical resistivity, carrier concentration, and carrier mobility of the disclosed TCF formed of SrₓNbO_{3-d} are shown in FIGS. 1A - 1D. FIG. 1A is a plot of the resistivity p as a function of the thickness of the TCF. FIG. 1B is a plot of the carrier concentration n as a function of the thickness of the TCF. FIG. 1C is a plot of the electron mobility µ as a function of the thickness of the TCF. FIG. 1D is a plot of the sheet resistance Rₛ as a function of the thickness of the TCF. In each of the plots, the SrₓNbO_{3-d} is a RF sputtered TCF.

In some embodiments, the TCF has a resistivity at 25° C. of about 1 × 10⁻⁶ Ω·cm to about 1 × 10⁻² Ω·cm. In some embodiments, the TCF has a resistivity of about 2 × 10⁻⁶ Ω·cm, about 3 × 10⁻⁶ Ω·cm, about 4 × 10⁻⁶ Ω·cm, about 5 × 10⁻⁶ Ω·cm, about 6 × 10⁻⁶ Ω·cm, about 7 × 10⁻⁶ Ω·cm, about 8 × 10⁻⁶ Ω·cm, about 9 × 10⁻⁶ Ω·cm, about 1 × 10⁻⁵ Ω·cm, about 1 × 10⁻⁴ Ω·cm, about 1 × 10⁻³ Ω·cm, about 1 × 10⁻² Ω·cm, or any range that is defined by one or more of the above resistivity values. In some embodiments, the TCF a resistivity of about 1 × 10⁻⁴ Ω·cm, about 2 × 10⁻⁴ Ω·cm, about 3 × 10⁻⁴ Ω·cm, about 4 × 10⁻⁴ Ω·cm, about 5 × 10⁻⁴ Ω·cm, about 6× 10⁻⁴ Ω·cm, about 7 × 10⁻⁴ Ω·cm, about 8 × 10⁻⁴ Ω·cm, or about 9× 10⁻⁴ Ω·cm. In some embodiments the TCF has a minimum resistivity at 25° C. of about (3.2 ± 1.5) × 10⁻⁴ Ω·cm. In other embodiments, the TCF has a minimum resistivity of about 3.81 × 10⁻⁵ Ω·cm. In other embodiments, the films have a resistivity of about 1.79 × 10⁻⁴ Ω·cm to about 7 × 10⁻⁴ Ω·cm.

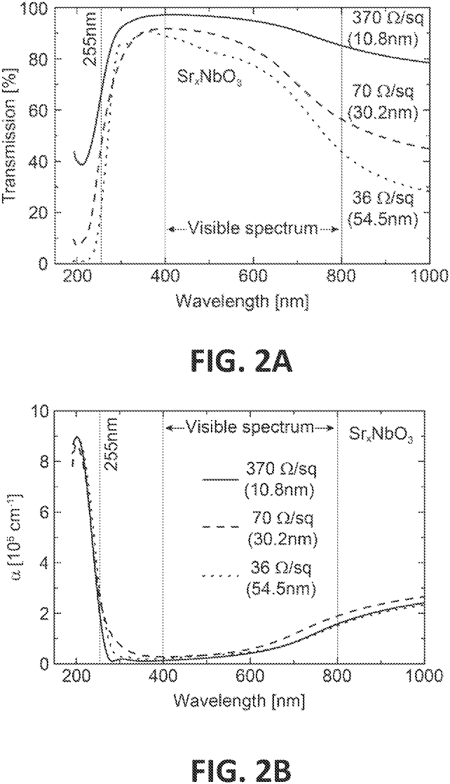

The SrₓNbO_{3-d} TCF of the disclosure also has excellent optical properties with respect to visible and UV spectrum. Refractive index, extinction coefficient, absorption coefficient, and optical transmission of the TCF formed of SrₓNbO_{3-d} are shown in FIGS. 2A -2D. FIG. 2A is a plot of the transmission of light through the TCF versus the wavelength of the light for three tested films of thicknesses of 10.8 nm, 30.2 nm, and 54.5 nm, with markings to show the location of the visible spectrum and of 255 nm which is within the UV-C band. As shown in FIG. 2A, the transmission in the visible spectrum is about 86% to about 97% for a 10.8 nm thick TCF having a sheet resistance of 370 Ω/sq, about 56% to about 91% for a 30.2 nm thick TCF having a sheet resistance of 70 Ω/sq, and about 44% to about 89% for a 54.5 nm thick TCF having a sheet resistance of 36 Ω/sq. Also shown in FIG. 2A, the transmission of UV-C light having a wavelength of 255 nm is about 66% for a TCF having a thickness of 10.8 nm, about 47% for a TCF having a thickness of 30.2 nm, or about 22% for a TCF having a thickness of about 54.5 nm.

Similar to FIG. 2A, FIG. 2B is a plot of the absorption coefficient of the TCF formed of SrₓNbO_{3-d}. FIG. 2C is a plot of the extinction coefficient of the TCF formed of SrₓNbO_{3-d}. FIG. 2D is a plot of the refractive index of the TCF formed of SrₓNbO_{0-d}.

In still other embodiments, the TCF has a visible light transmittance of about 30%, about 40%, about 50%, about 60%, about 70%, about 80%, about 90%, about 95%, or any range formed of two of the preceding values when the TCF has a thickness of about 10 nm to about 60 nm. Additionally, the TCF has a transmittance at a wavelength of 255 nm of about 15% to about 80% when the TCF has a thickness of about 10 nm to about 60 nm.

In some embodiments, the TCF is SrₓMoO_{3-d} and the transmission is about 32% to about 66% for light of wavelength of about 240 nm to about 320 nm while simultaneously achieving a resistivity of about 1 × 10⁻² Ω·cm to about 5 × 10⁻⁵ Ω·cm and having about 10% Sr vacancies. In some embodiments, the TCF is SrₓMoO_{3-d} and the transmission is about 32% to about 66% for light of wavelength of about 240 nm to about 320 nm while simultaneously achieving a resistivity of about 1 × 10⁻² Ω·cm to about 5 × 10⁻⁵ Ω·cm and having about 10% Sr vacancies.

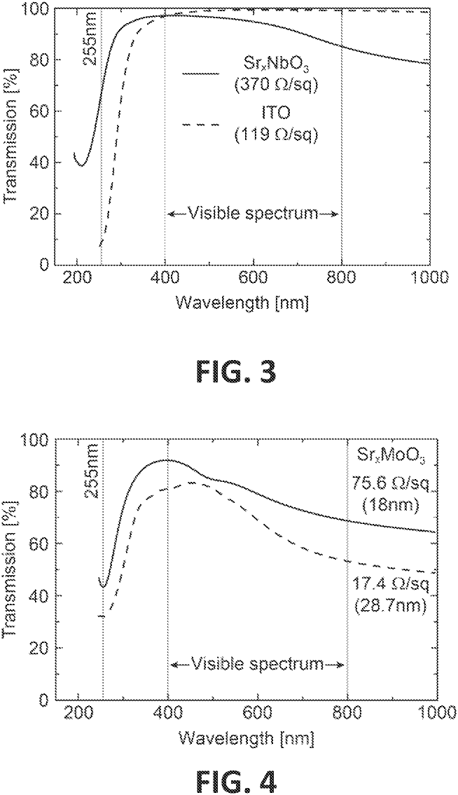

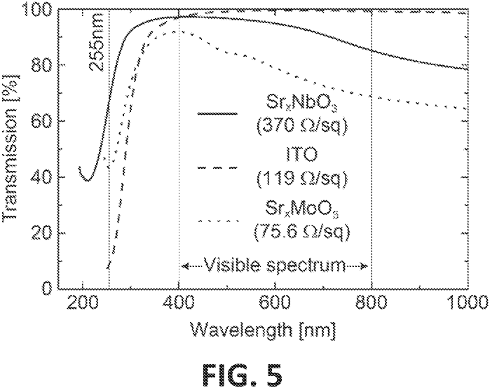

FIG. 4 is plot of the transmission of light through a TCF formed of SrₓMoO_{3-d} for two tested films of thicknesses of 18 nm and 28.7 nm, with markings to show the location of the visible spectrum and of 255 nm which is within the UV-C band. FIG. 4 shows that the transmission of light in both the visible spectrum the UV portion of the spectrum is effective with only minor reductions in transmission even when the thickness of the TCF is increased from 18 nm to 28.87 nm. FIG. 5 plots a comparison of the transmission of light through three TCF formed of SrₓNbO₃, ITO, and SrₓMoO₃, with markings to show the location of the visible spectrum and of 255 nm which is within the UV-C band.

### Applications and Articles

The potential applications and uses of the TCF of the disclosure are not limited. In some embodiments, the SrₓNbO_{3-d} TCF of the disclosure is included in an electronic device. Electronic devices include one or more of liquid crystal displays (LCD), plasma display panels (PDP), capacitive touch panels, capacitive touch sensors, resistive touch sensors, electrophoretic display panels, organic light emitting diodes (OLED), photovoltaic cells, resistance heaters, smart windows, light emitting diodes (LEDs), photovoltaic cells for UV applications, photodiodes for UV applications, transparent antennas for radio frequency identification (RFID), transparent sensor arrays, transparent battery electrodes, transparent radio frequency coils for antennas, or transparent radio frequency coils for inductive electrical power transmission. Within these and other applications, the TCF of the disclosure is included in one or more electrical components. The electrical component includes one or more of antistatic coatings, electromagnetic interference (EMI) coatings, electrical traces, current spreading layers, optical index matching layers, electrodes, optical filtering layers, antireflection coatings, cathodes, anodes, strain gauges and any transparent articles that require electrical or thermal conductivity.

In some embodiments, the TCF of the disclosure is an electrical component of a LED that emits UV light. When included in UV LEDs, widespread use can be achieved for water disinfection, air sterilization, surface sterilization, food packaging sterilization, and the like in homes, hospitals, hotel rooms, and food processing facilities. Further applications include counterfeit detection, high-density optical recording, polymer curing, horticulture, plant growth lighting, phototherapy, three dimensional printing, resin printing, stereolithography, gas detection, particle detection, aerosol detection, biomolecule detection, or DNA lab on chip devices. When one or more TCF are deposited on a substrate, it is referred to herein as an optical stack, even if the resultant structure is not itself used for optical purposes.

### EXAMPLES

A ceramic target of phase pure pyrochlore strontium niobate (Sr₂Nb₂O₇) was synthesized using known powder processing techniques. Stoichiometric quantities of SrCO₃ and Nb₂O₅ were ground in a ball mill for 24 hours. The resulting powder was calcined in a covered crucible in air at 1200° C. for 24 hours. The calcined powder was milled for another 24 hours on a vibratory mill and was subsequently subjected to cold isostatic pressing to 200 MPa. The sputter target was sintered in a covered crucible in argon at 1500° C. for 12 hours. A target density (2.54 cm diameter) equal to 96% of the theoretical density (5820 kg/m³) was calculated using Archimedes’ principle. Phase purity was verified using a MALVERN PANALYTICAL EMPYREAN X-ray diffractometer in Bragg-Brentano geometry.

Following the synthesis of the target, SrₓNbO₃ films were grown on the (001) plane of 10 × 10 mm² single crystal (La_{0.3}Sr_{0.7})(Al_{0.65}Ta_{0.35})O₃ (LSAT) substrates. The Sr2Nb₂O₇ target was RF sputtered using a magnetron source (TORUS TM1) in a growth chamber with a base pressure of < 3 × 10⁻⁸ Torr (< 3.999 × 10⁻⁶ Pa). Chamber pressure during sputter deposition was set to 2.0 × 10⁻² Torr (2.666 Pa) of Ar to maximize the deposition rate. A growth temperature of 700° C. was used for all films. Under these conditions, the growth rate was found to be approximately 0.6 nm/min. All parameters besides growth time were maintained to achieve a thickness series of films. After growth, all films were first inspected by Reflection High Energy Electron Diffraction (RHEED). All other film analysis techniques were performed ex-situ. Film thickness and lattice parameter were determined using a MALVERN PANALYTICAL X’PERT3 MRD 4-circle diffractometer using Cu-K_{α1} radiation and GenX fitting software. Film surface morphologies were measured using a Bruker Dimension Icon AFM in peak force tapping mode.

A summary of the above target and the deposited film appears in Table 1 below:

TABLE 1

Target and Sample Stoichiometry

| Sample | σ/α | O Content (at.%) | Sr Content (at. %) | Nb Content (at.%) | Sr / Nb at. Ratio |
|---|---|---|---|---|---|
| Sr₂Nb₂O₇ (Target) | N/A | 61.7 ± 0.5 | 18.9 ± 0.5 | 18.9 ± 0.5 | 1.00±0.03 |
| SrₓNbO₃ (23.2 nm thick) | 0.013 | 61.8±0.5 | 16.8±0.5 | 021.5±0.5 | 0.78±0.03 |
| SrₓNbO₃ (54.4 nm thick) | 0.060 | 61.8±0.5 | 14.8±0.5 | 23.4±0.5 | 0.63±0.03 |
| SrₓNbO₃ (55.7 nm thick) | 0.063 | 62.2±0.5 | 17.4±0.5 | 20.7±0.5 | 0.84±0.03 |

The deposited films were also analyzed using scanning transmission electron microscopy (STEM). A FEI HELIOS NANOLAB 660 focused ion beam (FIB) system using Ga+ ions was used to prepare a cross-sectional sample of SrNbO₃ for STEM. Approximately 10 µm of carbon was deposited to prevent Ga implementation to the surface film. The initial lift-out sample was 20 µm × 2.5 µm. The sample was then carbon welded onto a copper V post TEM grid. The V notch was deepened to avoid copper redeposition during ion beam milling. The sample was gradually thinned, resulting in a final polishing of 2 keV and 9 pA.

A double-aberration-corrected FEI TITAN3 G2 STEM was used to image the sample at 300 keV. High-angle annual dark field STEM imaging was completed using Fischione detectors at a camera length of 115 mm with convergence angle of 29.98 mrad and a frame time of 20.1 seconds. Images were drift-corrected by combining two orthogonal scanned probe images into a single image using kernel density estimation and Fourier filtering to produce a combined image from all components.

To determine electrical and optical properties, temperature-dependent resistivity and Hall measurements were taken. Ellipsometric spectra were collected at room temperature at three angles of incidence (50°, 60°, and 70°) using a rotating-compensator spectroscopic ellipsometer over the spectral range from 1.24 to 6.41 eV (0.194 - 1.000 µm). Spectra in n and k were extracted using a least-squares regression analysis and an unweighted error function to fit the experimental ellipsometric spectra based on an optical model consisting of a semi-infinite LSAT substrate (obtained by measuring the ellipsometric spectra of a bare LSAT substrate from the same batch), SrₓNbO₃ film, and surface roughness. The surface roughness was represented by a Bruggeman effective medium approximation of 0.5 void + 0.5 film material fractions. The parameterization of n included combinations of Sellmeier, Lorentz, Tauc-Lorentz, and Drude oscillators. Oscillator parameters as well as thicknesses of the SrₓNbO₃ film and the surface roughness layer were used as fitting parameters.

To measure stoichiometry, XPS measurements were performed using a PHYSICAL ELECTRONICS VERSAPROBE II instrument equipped with a monochromatic Al K_{α} X-ray source (hv = 1486.7 eV) and a concentric hemispherical analyzer. Charge neutralization was performed using both low energy electrons (<5 eV) and argon ions. The binding energy axis was calibrated using sputter cleaned Cu (Cu 2p_{3/2} = 932.62 eV, Cu 3p_{3/2} = 75.1 eV) and Au foils (Au 4f_{7/2} = 83.96 eV). Peaks were charge referenced to Sr²⁺ band in the Sr 3d spectra at 133.2 eV. Measurements were taken at a takeoff angle of 85° with respect to the sample surface plane. This resulted in a typical sampling depth of 4-7 nm (95% of the signal originated from this depth or shallower). As the target material had the desired Sr/Nb ratio of the films, it was used as a standard material. Therefore relative sensitivity factors acquired from XPS measurements of an air-cleaved Sr2Nb₂O₇ target prior to any deposition were used to determine the Sr and Nb composition of the sputter deposited films.

In the above detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, et cetera. As a non-limiting example, each range discussed herein can be readily broken down into a lower third, middle third and upper third, et cetera. As will also be understood by one skilled in the art all language such as “up to,” “at least,” and the like include the number recited and refer to ranges that can be subsequently broken down into subranges as discussed above. Finally, as will be understood by one skilled in the art, a range includes each individual member. Thus, for example, a group having 1-3 layers refers to groups having 1, 2, or 3 layers. Similarly, a group having 1-5 layers refers to groups having 1, 2, 3, 4, or 5 layers, and so forth.

The above-disclosed and other features and functions, or alternatives thereof, may be combined into many other different systems or applications. Various presently unforeseen or unanticipated alternatives, modifications, variations or improvements therein may be subsequently made by those skilled in the art, each of which is also intended to be encompassed by the disclosed embodiments.

1. A transparent conductive film (TCF) comprising A_{×}BO_{3-d} having a transmittance of about 50% to about 95% for light having a wavelength from about 240 nm to about 320 nm when measured for a TCF having a thickness of about 10 nm.

2. The TCF of claim 1, wherein the transmittance of the TCF is about 80% or more at a wavelength of 550 nm when measured for a TCF having a thickness of 10 nm.

3. The TCF of claim 1, wherein the TCF comprises A_{×}BO_{3-d} having a transmittance of about 50% to about 95% for light having a wavelength from about 240 nm to about 320 nm, where A is one or more of a monovalent, divalent, or trivalent cation including Li, Na, K, Rb, Be, Mg, Ca, Sr, Ba, Sc, Y, La, Pr, Nd, Sm, Eu, Gd, Tb, Dy, Ho, Er, Tm, Yb, Lu, B is one or more of Ti, Zr, Hf, Nb, Ta, Cr, Mo, V, or W, x is about 0.30 to about 0.95 and the TCF has a perovskite crystal structure, a perovskite-like crystal structure that approximates a perovskite crystal structure, or some combination of the preceding crystal structures.

4. The TCF of claim 3, wherein A is four or more of a monovalent, divalent, or trivalent cation including Li, Na, K, Rb, Be, Mg, Ca, Sr, Ba, Sc, Y, La, Pr, Nd, Sm, Eu, Gd, Tb, Dy, Ho, Er, Tm, Yb, or Lu.

5. The TCF of claim 3, wherein B is four or more of Ti, Zr, Hf, Nb, Ta, Cr, Mo, V, or W.

6. The TCF of claim 3, wherein the perovskite crystal structure, perovskite-like crystal structure, or combination of the perovskite and perovskite-like crystal structures has an amount of A vacancy of greater than about 15%.

7. The TCF of claim 1, wherein the ratio of A and O is about 3.

8. The TCF of claim 1, wherein A is Sr and B is Nb.

9. The TCF of claim 1, wherein A is Sr and B is Mo.

10. The TCF of claim 1, wherein the TCF is formed by radio frequency (RF) sputtering.

11. An optical stack comprising a substrate and a transparent conductive film (TCF) comprising A_{×}BO_{3-d} having a transmittance of about 50% to about 95% for light having a wavelength from about 240 nm to about 320 nm, wherein A is one or more of a monovalent, divalent, or trivalent cation including Li, Na, K, Rb, Be, Mg, Ca, Sr, Ba, Sc, Y, La, Pr, Nd, Sm, Eu, Gd, Tb, Dy, Ho, Er, Tm, Yb, Lu, B is one or more of Ti, Zr, Hf, Nb, Ta, Cr, Mo, V, or W, x is about 0.30 to about 0.95 and the TCF has a perovskite crystal structure, a perovskite-like crystal structure that approximates a perovskite crystal structure, or some combination of the preceding crystal structures.

12. The optical stack of claim 11, wherein A is four or more of a monovalent, divalent, or trivalent cation including Li, Na, K, Rb, Be, Mg, Ca, Sr, Ba, Sc, Y, La, Pr, Nd, Sm, Eu, Gd, Tb, Dy, Ho, Er, Tm, Yb, or Lu.

13. The optical stack of claim 11, wherein B is four or more of Ti, Zr, Hf, Nb, Ta, Cr, Mo, V, or W.

14. The optical stack of claim 11, wherein the substrate is one or more of SrTiO₃ BaTiO₃, PZT, PMN-PT, BiFeO₃, CaTiO₃, LiNbO₃, ferroelectric compounds, monocrystalline silicon, polycrystalline silicon, amorphous silicon, monocrystalline germanium, polycrystalline germanium, amorphous germanium, quartz, glass, metal, plastic, an oxide coated surface, crystalline sapphire (Al₂O₃), crystalline SiC, crystalline GaN, or monocrystalline (La_{0.3}Sr_{0.7})(Al_{0.65}Ta_{0.35})O₃ (LSAT).

15. The optical stack of claim 11, wherein there is a lattice mismatch between the substrate and the TCF that is greater than about 1%.

16. The optical stack of claim 11, wherein A is Sr and B is Nb.

17. The optical stack of claim 11, wherein A is Sr and B is Mo.

18. A method of manufacturing an optical stack comprising:
providing a substrate, and
radio frequency (RF) sputtering a TCF on the substrate,
wherein the TCF includes A_{×}BO_{3-d} having a transmittance of about 50% to about 95% for light having a wavelength from about 240 nm to about 320 nm, where x is about 0.30 to about 0.95 and the resultant TCF has a perovskite crystal structure.

19. The method of claim 18, wherein the RF sputtering is performed in a reducing atmosphere.

20. The method of claim 18, wherein the perovskite crystal structure is stabilized by introducing vacancies into the TCF that are electrically compensated.
